(19) United States
(12) Patent Application Publication
(10) Pub. No.: US 2017/0077178 A1
(43) Pub. Date: Mar. 16, 2017

(54) NONVOLATILE STORAGE DEVICE, SEMICONDUCTOR ELEMENT, AND CAPACITOR

(71) Applicant: Kabushiki Kaisha Toshiba, Minato-ku (JP)

(72) Inventors: Hisao MIYAZAKI, Yokohama (JP); Tadashi SAKAI, Yokohama (JP); Yuichi YAMAZAKI, Inagi (JP); Masayuki KATAGIRI, Kawasaki (JP)

(73) Assignee: Kabushiki Kaisha Toshiba, Minato-ku (JP)

(21) Appl. No.: 15/251,448

(22) Filed: Aug. 30, 2016

(30) Foreign Application Priority Data
Sep. 10, 2015 (JP) 2015-178910

(51) Int. Cl. H01L 27/24; H01L 45/00; H01L 49/02; H01L 23/528; H01L 23/532

(52) U.S. Cl. CPC H01L 27/2418; H01L 23/5283; H01L 23/53276; H01L 28/40; H01L 45/1233

(57) ABSTRACT

A nonvolatile storage device of an embodiment includes a first wiring layer extending in a first direction, a second wiring layer extending in a second direction intersecting with the first direction, a conductive layer between the first wiring layer and the second wiring layer at an intersection of the first wiring layer and the second wiring layer, and a resistance change region including at least one of an oxide, a nitride, and an oxynitride in the first wiring layer. The resistance change region exists in the first wiring layer including an interface between the first wiring layer and the conductive layer.

### CROSS-REFERENCE TO RELATED APPLICATION

This application is based upon and claims the benefit of priority from Japanese Patent Application No. 2015-178910, filed on Sep. 10, 2015; the entire contents of which are incorporated herein by reference.

### FIELD

Embodiments described herein relate to a nonvolatile storage device, semiconductor element, and capacitor.

### BACKGROUND

A nonvolatile storage device is one of most micronized semiconductor devices, and increase in a wiring resistance due to micronization of metal wiring in accordance therewith is concerned. When metal wiring is used, it is estimated that an action itself as a nonvolatile storage device will be difficult in a case of a wiring width of about 10 nm. Therefore, a wiring material alternative to a metal is desired. Graphene is a major candidate for the alternative wiring material.

### BRIEF DESCRIPTION OF THE DRAWINGS

FIG. 1 is a schematic cross sectional view of a nonvolatile storage device according to an embodiment;

FIG. 2 is a schematic perspective view of the nonvolatile storage device according to the embodiment;

FIG. 3 is a schematic cross sectional view of the nonvolatile storage device according to the embodiment;

FIG. 4 is a schematic cross sectional view of a first wiring layer and a conductive layer extracted from the nonvolatile storage device according to the embodiment;

FIG. 5 is a schematic cross sectional view of the nonvolatile storage device according to the embodiment;

FIGS. 6A, 6B, 6C, 6D, 6E, 6F, 6G, and 6H are schematic process views of the nonvolatile storage device according to the embodiment;

FIG. 7 is a schematic cross sectional view of a nonvolatile storage device according to an embodiment;

FIG. 8 is a schematic cross sectional view of a nonvolatile storage device according to an embodiment;

FIG. 9 is a schematic cross sectional view of a semiconductor element according to an embodiment; and

FIG. 10 is a schematic cross sectional view of a capacitor according to an embodiment.

### DETAILED DESCRIPTION

A nonvolatile storage device of an embodiment includes a first wiring layer extending in a first direction, a second wiring layer extending in a second direction intersecting with the first direction, a conductive layer between the first wiring layer and the second wiring layer at an intersection of the first wiring layer and the second wiring layer, and a resistance change region including at least one of an oxide, a nitride, and an oxynitride in the first wiring layer. The resistance change region exists in the first wiring layer including an interface between the first wiring layer and the conductive layer.

### First Embodiment

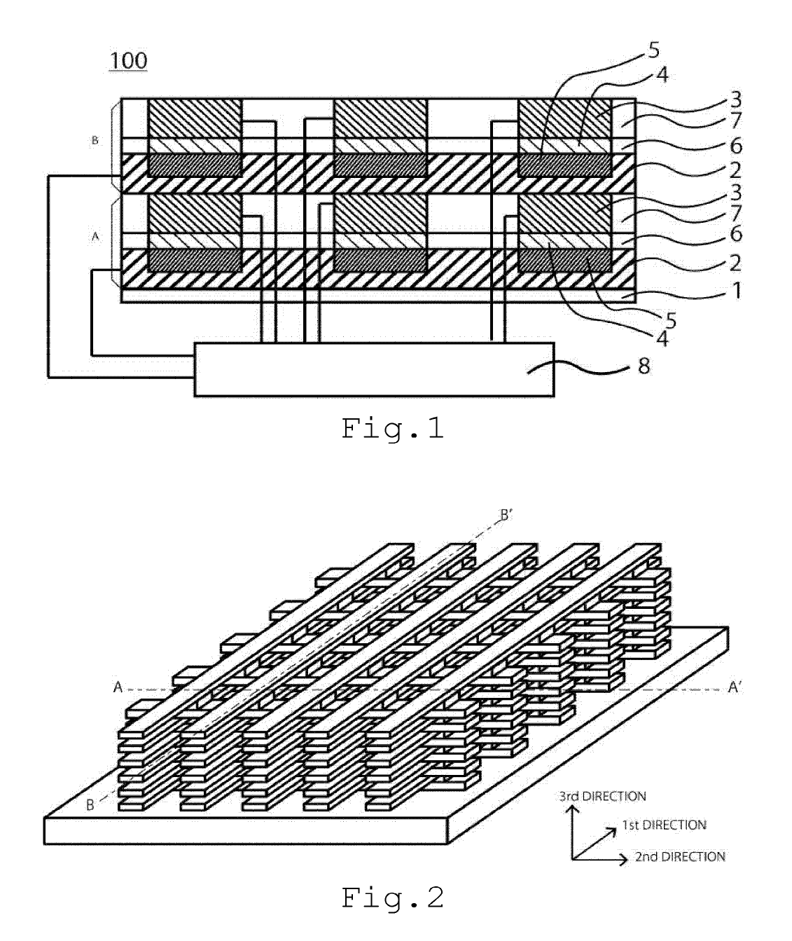

A first embodiment relates to a nonvolatile storage device using a graphene conductor. Hereinafter, the nonvolatile storage device of the first embodiment will be described with reference to FIGS. 1 to 5. FIG. 1 illustrates a schematic cross sectional view of a nonvolatile storage device 100 of the first embodiment. The nonvolatile storage device in FIG. 1 includes a substrate 1, a first wiring layer 2 extending in a first direction, a second wiring layer 3 extending in a second direction intersecting with the first direction, a conductive layer 4 between the first wiring layer 2 and the second wiring layer 3 at an intersection of the first wiring layer 2 and the second wiring layer 3, a resistance change region 5 including at least one of an oxide, a nitride, and an oxynitride in the first wiring layer 2, a first insulating layer 6 sandwiching the conductive layer 4, and a second insulating layer 7 sandwiching the second wiring layer 3. The resistance change region 5 exists in a region including a surface of the first wiring layer 2. The first wiring layer 2 is connected to the conductive layer 4 through the resistance change region 5. A third insulating layer 9 not illustrated in FIG. 1 exists in the nonvolatile storage device 100, and sandwiches the first wiring layer 2. The first wiring layer 2 and the second wiring layer 3 are connected to a control unit 8. The nonvolatile storage device of the first embodiment is a resistive random access memory (ReRAM) including a memory element in an intersection region of the first wiring layer 2 and the second wiring layer 3. In the schematic cross sectional view of FIG. 1, two laminating patterns in each of which the first wiring layer 2 intersects with the second wiring layer 3 are laminated. The laminating number of the laminating patterns is n (n is an integer of one or more). A structure obtained by laminating each of the first wiring layer 2, the second wiring layer 3, and the conductive layer 4 is referred to as a wiring laminated body. The schematic view of FIG. 1 illustrates a first wiring laminated body A and a second wiring laminated body B from a side of the substrate. The nonvolatile storage device 100 includes a monolayer or multilayer wiring laminated body.

(Substrate 1)

The substrate 1 is a substrate of the nonvolatile storage device 100. As the substrate 1, a substrate used for a semiconductor device, such as a Si substrate, can be used without any particular limitation.

(First Wiring Layer 2)

The first wiring layer 2 extending in a first direction exists between the substrate 1 and the conductive layer 4 and between the substrate 1 and the first insulating layer 6. As the first wiring layer 2, a multilayer graphene obtained by laminating a graphene sheet can be used. The graphene sheet to constitute the multilayer graphene is a planar graphene sheet. The planar graphene sheet does not have a cylindrical shape or a spherical shape such as carbon nanotube or fullerene, but has edges on four sides of the graphene sheet. The planar graphene sheet has edges in a length direction of wiring and a width direction thereof. The planar graphene sheet is laminated in a height direction of wiring. Not the edges of the multilayer graphene of the first wiring layer 2 but an uppermost surface or a lowermost surface thereof is connected to the substrate 1 or the conductive layer 4. The first wiring layer 2 preferably has a linear wiring pattern shape. The planar graphene sheet is preferably a graphene sheet of a polycrystalline graphene having a grain boundary or a defect. An edge of a graphene sheet of the multilayer graphene to constitute a side surface of the first wiring layer 2 in a wiring length direction is preferably connected to the control unit 8 electrically. An edge of a graphene sheet of the multilayer graphene to constitute a side surface of the first wiring layer 2 in a wiring width direction is preferably connected to a layer for suppressing leakage of an interlayer substance or an insulating film.

FIG. 2 illustrates a schematic perspective view obtained by extracting the first wiring layer 2, the second wiring layer 3, and the conductive layer 4. FIG. 2 illustrates a schematic view of a nonvolatile storage device in which the first wiring layer 2 and the second wiring layer 3 intersect with each other and are laminated. As illustrated in FIG. 2, by causing the first wiring layer 2 and the second wiring layer 3 to intersect with each other and laminating the first wiring layer 2 and the second wiring layer 3, a nonvolatile storage device having a high density can be obtained. The schematic perspective view of FIG. 2 illustrates a structure in which six wiring laminated bodies are laminated.

The first direction is not parallel to the second direction of the second wiring layer 3. When a plurality of the first wiring layers 2 exists, the plurality of first wiring layers 2 is preferably disposed in parallel to one another, and is preferably disposed at equal intervals. An angle between the first direction and the second direction is preferably 90°. FIG. 1 is a schematic cross sectional view of a part of a cross section cut along A-A′ in FIG. 2.

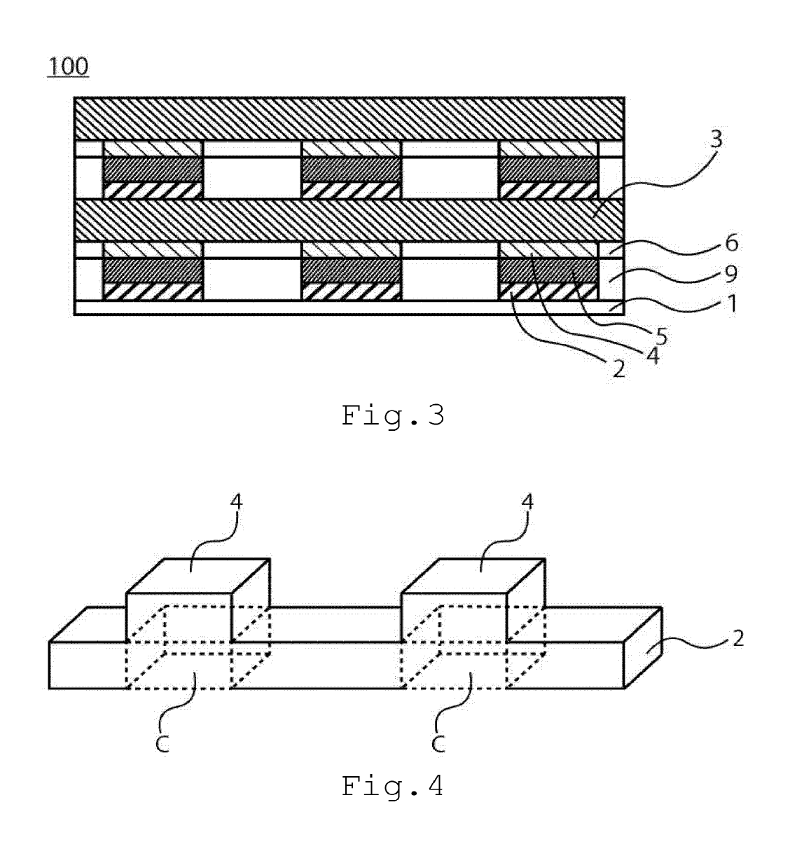

FIG. 3 illustrates a schematic cross sectional view of a part of a cross section cut along B-B′ in FIG. 2. Similarly to FIG. 1, the schematic view of FIG. 3 includes the substrate 1, the first wiring layer 2 extending in the first direction, the second wiring layer 3 extending in the second direction intersecting with the first direction, the conductive layer 4 at an intersection of the first wiring layer 2 and the second wiring layer 3, the resistance change region 5 including at least one of an oxide, a nitride, and an oxynitride in the first wiring layer 2, the first insulating layer 6 sandwiching the conductive layer 4, and the second insulating layer 7 sandwiching the second wiring layer 3. FIGS. 1 and 3 are different from each other in the width direction of constituent elements such as the first wiring layer 2, the second wiring layer 3, and the conductive layer 4, and the length direction thereof.

An electron state of a graphene sheet to constitute the multilayer graphene is preferably a semiconductor due to a quantum confinement effect. Therefore, for example, the wiring width of the first wiring layer 2 is preferably 2 nm or more and 20 nm or less. FIG. 3 illustrates a width direction W1 of the first wiring layer 2. An interlayer substance of the first wiring layer 2 preferably exists between layers of the multilayer graphene. Existence of the interlayer substance between layers of the multilayer graphene preferably reduces a resistance of the multilayer graphene. The interlayer substance may exist not only between layers of the multilayer graphene but also on the layers. An interlayer distance of the multilayer graphene into which the interlayer substance has been inserted is from 0.335 nm, for example, to 0.7 nm to 1 nm. 0.335 nm is an interlayer distance of a plurality of graphene sheets to constitute the multilayer graphene into which the interlayer substance has not been inserted. Due to the first wiring layer 2 which has become a semiconductor due to a quantum confinement effect, the conductive layer 4, the resistance change region 5, and the first wiring layer 2 form a metal (M)-insulating body (I)-semiconductor (S) structure to cause a memory element to have a rectification function. In the embodiment, by providing a memory function and a rectification function due to change in a resistance among the conductive layer 4, the resistance change region 5, and the first wiring layer 2, a length in a third direction, that is, the thickness of the nonvolatile storage device can be reduced, and furthermore, the structure can be simplified.

For example, the number of layers of the multilayer graphene is preferably from 5 to 20. By the too small number of layers of the multilayer graphene, the resistance change region 5 easily exists from an upper surface of the first wiring layer 2 to a bottom surface thereof, and the wiring length direction of the first wiring layer 2 becomes easily highly-resistant. A high resistance of the wiring length direction of the first wiring layer 2 caused by the resistance change region 5 is not preferable because a resistance variation in the plurality of first wiring layers 2 is large, and an action of a memory is damaged. In addition, the too large number of layers is not preferable because a wiring height is increased to increase the size of the nonvolatile storage device. For example, a height H1 of the first wiring layer 2 is 3.5 nm or more and 20 nm or less in view of these.

The interlayer substance is an atom or a molecule to supply a carrier (an electron or a hole) to a graphene sheet. The interlayer substance preferably contains at least one of a metal chloride, a metal fluoride, a metal bromide, and a metal oxide. As a metal element contained in the metal chloride, the metal fluoride, the metal bromide, and the metal oxide, at least one element selected from the group consisting of; Ta, Ti, Ni, Fe, Mo, Hf, Co, Cu, Ag, Zn, W, Al, Zr, Cr, V, Bi, and Mn is preferable. As the interlayer substance, a halogen such as F₂, Cl₂, Br₂, or or an interhalogen compound such as IBr or ICl may be used.

Specific examples of the metal chloride in the interlayer substance include TaCl₅, NiCl₂, TiCl₄, FeCl₃, MoCl₅, HfCl, CoCl₂, CuCl₂, AgCl, ZnCl₂, WCl₆, AlCl₃, ZrCl, BiCl₃, and MnCl₂.

Specific examples of the metal fluoride in the interlayer substance include TaF₅, NiF₂, TiF₄, FeF₃, MoF₅, HfF, CoF₂, CuF₂, AgF, ZnF₂, WF₆, AlF₃, ZrF, and MnF₂. Specific examples of the metal bromide in the interlayer substance include TaBr₅, NiBr₂, TiBr₄, BreBr₃, MoBr₅, HfBr, CoBr₂, CuBr₂, AgBr, ZnBr₂, WBr₆, AlBr₃, ZrBr, and MnBr₂.

Specific examples of the metal oxide in the interlayer substance include CrO₃, MoO₃, V₂O₅, and WO₃.

The interlayer substance can be confirmed by change in Raman shift of the multilayer graphene between layers of which the interlayer substance exists. Existence of the interlayer substance between layers of the multilayer graphene of the first wiring layer 2 makes the multilayer graphene a p-type or an n-type. That is, by existence of the interlayer substance, the first wiring layer 2 becomes a p-type semiconductor wiring layer or an n-type semiconductor wiring layer.

The second wiring layer 3 extending in the second direction is sandwiched by the second insulating layer 7. The conductive layer 4 is sandwiched by the second wiring layer 3 and the resistance change region 5. A wiring layer, an insulating layer, or a nonvolatile storage device structure (not illustrated) may be further disposed in an upper portion of the second wiring layer 3. The second wiring layer 3 itself is common to the first wiring layer 2 except for presence or absence of the resistance change region 5. Description of the second wiring layer 3 common to the first wiring layer 2 will be omitted.

The height of the second wiring layer 3 is represented by H3, and the wiring width thereof is represented by W3. The second direction which is a wiring direction of the second wiring layer 3 is different from the first direction which is a wiring direction of the first wiring layer 2. That is, the second wiring layer 3 and the first wiring layer 2 are not parallel to each other. The planar graphene sheet is preferably a multilayer graphene laminated in a height direction of wiring. Not the edges of the multilayer graphene of the second wiring layer 3 but an uppermost surface (plane of the graphene) or a lowermost surface (plane of the graphene) thereof is connected to an upper layer portion (not illustrated) of the second wiring layer 3 or the conductive layer 4.

The interlayer substances of the first wiring layer 2 and the second wiring layer 3 may be the same as or different from each other. Conductivity types of the first wiring layer 2 and the second wiring layer 3 may be the same (n-type or p-type) as or different from each other.

The conductive layer 4 exists between the resistance change region 5 existing at least on a surface of the first wiring layer 2 and the second wiring layer 3. In the illustrated nonvolatile storage device 100, the conductive layer 4 exists at an intersection of the first wiring layer 2 and the second wiring layer 3. For example, the conductive layer 4 includes a metal. Specific examples of the conductive layer 4 include a metal layer, a conductive oxide layer, and a conductive nitride layer. The conductive layer 4 preferably contains at least one element selected from the group consisting of; Cu, Ag, Ti, Pt, Ta, W, Ni, Co, Al, Mo, Ir, Au, and Ru. The metal layer contains a metal, an alloy, or a conductive magnetic material. As the metal, at least one metal selected from the group consisting of; Cu, Ag, Ti, Pt, Ta, W, Ni, Co, Al, Mo, Ir, Au, and Ru can be used. As the alloy, an alloy obtained by combining two or more kinds of these metals can be used. As the conductive magnetic material, CeFeB or the like can be used as the conductive layer 4. As the conductive oxide, CaRuO₃ which is a perovskites type oxide or the like can be used as the conductive layer 4. As the conductive nitride, TiN, ZrN, NbN, TaN, Cr₂N, VN, or the like can be used as the conductive layer 4.

The resistance change region 5 exists at least on a surface of the first wiring layer 2. The resistance change region 5 exists in the first wiring layer 2 including an interface between the first wiring layer 2 and the conductive layer 4. When another layer exists between the conductive layer 4 and the resistance change region 5, the resistance change region 5 exists in the first wiring layer 2 including an interface between the first wiring layer 2 and the other layer. By existence of the resistance change region 5 in the interface between the first wiring layer 2 and the conductive layer 4 (other layer), a conductive path between the first wiring layer 2 and the second wiring layer 3 includes the conductive layer 4 and the resistance change region 5. The resistance change region 5 preferably exists in the entire interface between the first wiring layer 2 and the conductive layer 4.

Here, the resistance change region 5 will be described in detail with reference to the schematic perspective view of FIG. 4. The schematic perspective view of FIG. 4 illustrates the extracted first wiring layer 2 and conductive layer 4. A region surrounded by the broken line in the first wiring layer 2 is an intersection region C of the first wiring layer 2 and the conductive layer 4 in the first wiring layer 2. The intersection region C is a region sandwiched by the interface between the first wiring layer 2 and the conductive layer 4 and a surface of the first wiring layer 2 opposite to the interface between the first wiring layer 2 and the conductive layer 4. The resistance change region 5 exists in the intersection region C. Existence of a cross section of the first wiring layer 2 in a wiring width direction, the entire surface of which is the resistance change region 5, in the intersection region C is not preferable because the first wiring layer 2 becomes highly-resistant, and an action as a storage device is damaged. Therefore, the resistance change region 5 preferably exists in 70% (surface area) or less of the cross section of the first wiring layer 2 in the wiring width direction in the intersection region C. The resistance change region 5 more preferably exists in 50% (surface area) or less of the cross section of the first wiring layer 2 in the wiring width direction in the intersection region C. The resistance change region 5 preferably exists in 10% (surface area) or more and 50% (surface area) or less in the intersection region C. An existence ratio of more than 50% of the resistance change region 5 in the intersection region C is not preferable because a cross sectional area of a conductive portion of the first wiring layer 2 is too small. An existence ratio of less than 10% of the resistance change region 5 in the intersection region C is not preferable because a path not through the resistance change region 5 easily exists as a conductive path between the first wiring layer 2 and the second wiring layer 3.

In the first embodiment, a resistance between the first wiring layer 2 and the second wiring layer 3 can be changed by changing a resistance of the resistance change region 5. By changing a resistance value between the first wiring layer 2 and the second wiring layer 3, data can be written. By measuring a voltage or a current between the first wiring layer 2 and the second wiring layer 3, data can be read.

The resistance change region 5 contains at least one of an oxide, a nitride, and an oxynitride. Each of the conductive paths between the first wiring layer 2 and the second wiring layer 3 includes at least one of regions of an oxide, a nitride, and an oxynitride. As the oxide contained in the resistance change region 5, at least one of TaOx, NiOx, TiOx, FeOx, MoOx, HfOx, CoOx, CuOx, AgOx, ZnOx, WOx, AlOx, ZrOx, and MnOx is preferable. As the nitride contained in the resistance change region 5, at least one of AlN, NiN, and ZrN is preferable. As the oxynitride contained in the resistance change region 5, one or both of HfON and TiON are preferable. The oxide, the nitride, and the oxynitride in the resistance change region 5 exist between layers of the multilayer graphene of the first wiring layer 2. The oxide, the nitride, and the oxynitride have an insulating property or a high resistance. Therefore, the resistance change region 5 in a highly-resistant state has a higher resistance than a region other than the resistance change region 5 in the first wiring layer 2.

When the adjacent resistance change regions 5 are too close to each other, independence of adjacent memory elements is reduced by connection of the adjacent resistance change regions 5 or the like. A distance between the adjacent resistance change regions 5 is determined by a distance between wires of the first wiring layer 2 (wiring interval) and a distance between wires of the second wiring layer 3 (wiring interval). Each of the distance between wires of the first wiring layer 2 and the distance between wires of the second wiring layer 3 is preferably 3 nm or more, and more preferably 10 nm or more. The distance between wires of the first wiring layer 2 and the distance between wires of the second wiring layer 3 may be the same as or different from each other. A too large distance between wires is not preferable due to reduction of a memory density.

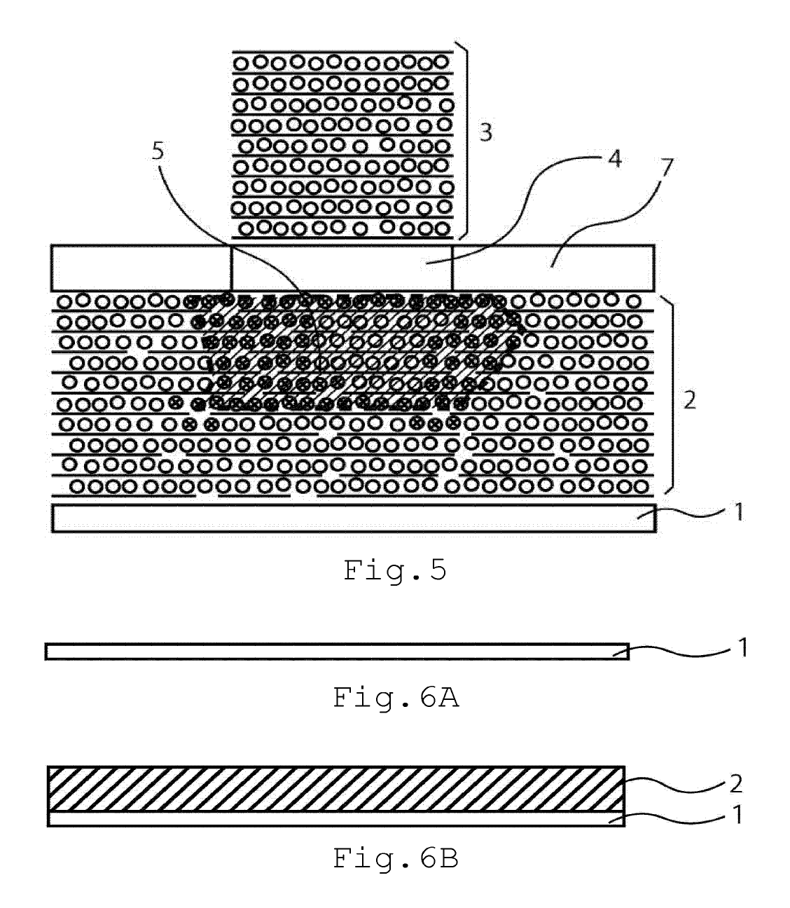

As illustrated in the schematic view of FIG. 5, the resistance change region 5 (hatched region) in which the multilayer graphene is surrounded by an oxide, a nitride, and an oxynitride exists. In the resistance change region 5, an interlayer substance not oxidized, not nitrided, or not oxynitrided preferably exists. As illustrated in the schematic view of FIG. 5, a conductive path between the first wiring layer 2 and the second wiring layer 3 is through the resistance change region 5, and therefore change in a resistance of the resistance change region 5 can be determined by conductivity between the first wiring layer 2 and the second wiring layer 3 selected. [0036] When at least one of the oxide, the nitride, and the oxynitride exists between layers of the multilayer graphene, a resistance value of the resistance change region 5 is changed by controlling an applied voltage between the first wiring layer 2 and the second wiring layer 3 and a voltage period with the control unit 8. For example, it is considered that change in a resistance is caused by formation and disconnection of a conductive path (metal filament) having a low resistance in the resistance change region 5. Existence of the conductive path (metal filament) having a low resistance in the resistance change region 5 improves conductivity of the resistance change region 5 in a lamination direction of the multilayer graphene and reduces a resistance of the resistance change region 5.

The first insulating layer 6 is an insulating layer sandwiching the conductive layer 4. The conductive layer 4 may be surrounded by the first insulating layer 6. As the first insulating layer 6, SiO₂ or the like can be used. The first insulating layer 6 and the second insulating layer 7 may be formed of the same material to form an integrated insulating film without a boundary between the first insulating layer 6 and the second insulating layer 7 or between the first insulating layer 6 and a third insulating layer 9.

The second insulating layer 7 is an insulating layer sandwiching the second wiring layer 3. As the second insulating layer 7, SiO₂ or the like can be used.

The third insulating layer 9 is an insulating layer sandwiching the first wiring layer 2. The schematic cross sectional view of FIG. 1 does not illustrate the third insulating layer 9 due to a relationship with the cross sectional direction, but the schematic cross sectional view of FIG. 3 illustrates the third insulating layer 9. As the third insulating layer 9, SiO₂ or the like can be used.

The control unit 8 connects the first wiring layer 2 to the second wiring layer 3. The control unit 8 controls writing, erasing, and reading of data with respect to a memory element. The control unit 8 selects any wiring layer of the plurality of first wiring layers 2 and any wiring layer of a plurality of the second wiring layers 3, and writes, erases, and reads data in a memory element at an intersection of the selected two wiring layers. The control unit 8 adjusts a voltage or a current to the selected two wiring layers, and thereby writes, erases, and reads data. The control unit 8 may include a control circuit for controlling the nonvolatile storage device 100, such as a controller for supplying a control signal and data to a memory element. The control unit 8 is not illustrated in the drawings other than FIG. 1. Another embodiment may include a control unit, but the control unit is not illustrated.

An action of the nonvolatile storage device will be described. The control unit 8 selects any wiring layer of the plurality of first wiring layers 2 and any wiring layer of the plurality of second wiring layers 3, and applies a voltage. Then, the control unit 8 controls a voltage applied to the resistance change region 5 or a current flowing in the resistance change region 5, and changes a resistance of the resistance change region 5 existing at an intersection of the first wiring layer 2 and the second wiring layer 3 selected. In a case of a memory element of one-bit memory, by changing a resistance for switching between on and off of the memory element, the control unit 8 writes information in the resistance change region 5 as the memory element (set). The control unit 8 selects any wiring layer of the plurality of first wiring layers 2 and any wiring layer of the plurality of second wiring layers 3, measures a resistance value between the first wiring layer 2 and the second wiring layer 3 selected, and thereby reads information. Then, the control unit 8 selects any wiring layer of the plurality of first wiring layers 2 and any wiring layer of the plurality of second wiring layers 3, and applies a voltage. Then, the control unit 8 controls a voltage applied or a current, changes a resistance of the resistance change region 5 existing at an intersection of the first wiring layer 2 and the second wiring layer 3 selected, and erases data (reset).

When data is written, one of a plurality of resistance regions may be written selectively. At this time, for example, a plurality of resistance regions such as a first resistance region, a second resistance region, a third resistance region, and a fourth resistance region is set. Then, the control unit 8 controls the selected resistance change region 5 so as to be within any resistance region.

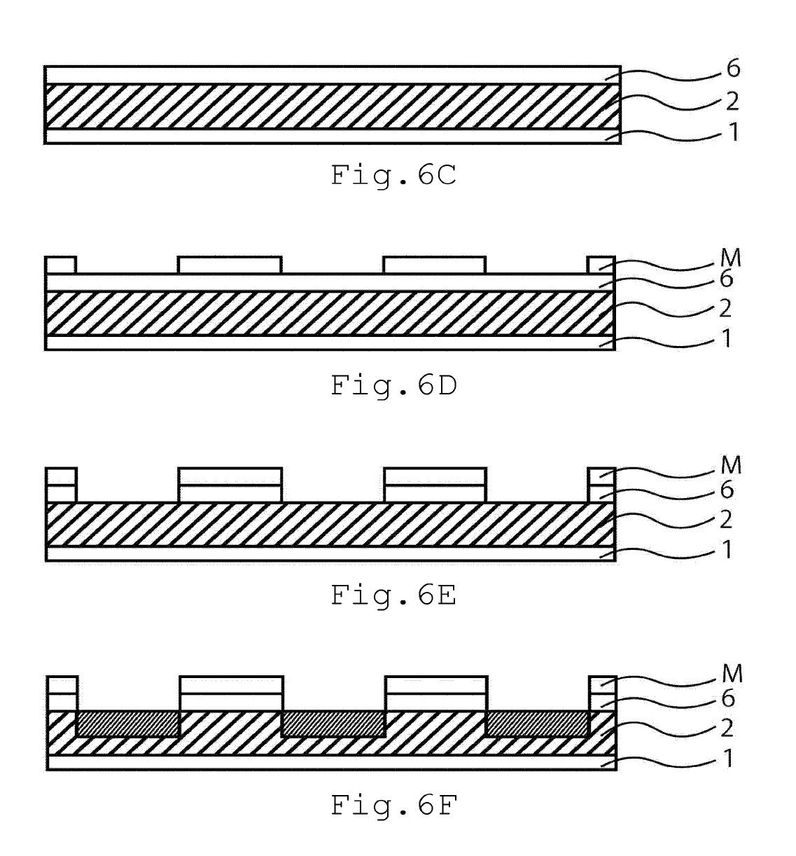

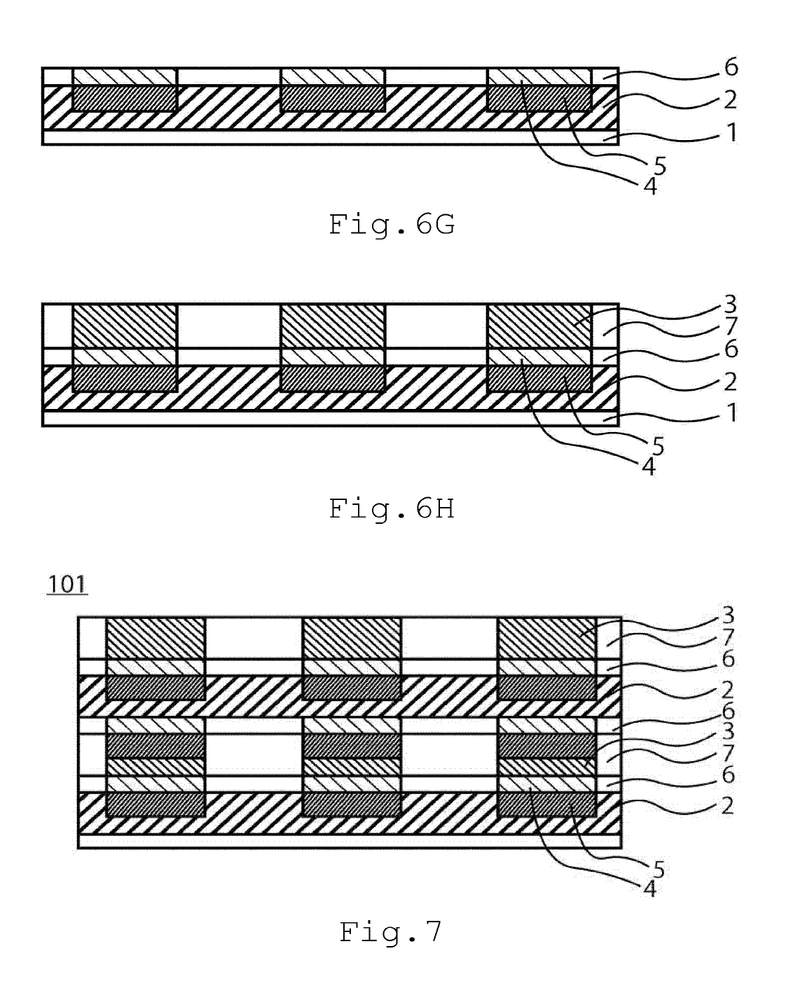

Next, an example of a method for manufacturing the nonvolatile storage device of the first embodiment will be described with reference to the schematic process views of FIGS. 6A to 6H. The plurality of first wiring layers 2 which has been processed into a wiring shape is transferred onto the substrate 1 in the schematic process view of FIG. 6A including the substrate 1 to obtain the structure in the schematic process view of FIG. 6B. Subsequently, the structure in FIG. 6B is treated with a gas including an interlayer substance, and the interlayer substance is inserted between layers of the first wiring layer 2. A spin on dielectric film (SOD film) is formed between layers of the first wiring layer 2 into which the interlayer substance has been inserted and an upper portion thereof. Then, the thickness of the upper portion of the first wiring layer 2 is adjusted by performing chemical mechanical polishing (CMP) to obtain the structure in FIG. 6C in which the first insulating layer 6 is formed between layers of the first wiring layer 2 and an upper portion thereof. Subsequently, a mask M for forming the resistance change region 5 is formed in an upper portion of the structure in FIG. 6C to obtain the structure in FIG. 6D. Subsequently, the first insulating layer 6 is etched using the mask M to obtain the structure in FIG. 6E having the first insulating layer 6 which has been subjected to pattern processing. Subsequently, the structure in FIG. 6E is treated with an atmosphere containing an oxidizing gas, a nitriding gas, or an oxidizing gas and a nitriding gas, and the resistance change region 5 is formed to obtain the structure in FIG. 6F. Subsequently, the conductive layer 4 is embedded in a void of the first insulating layer 6 which has been subjected to pattern processing, and the mask M is removed to obtain the structure in FIG. 6G. Then, the second wiring layer 3 and the second insulating layer 7 are formed similarly to obtain the structure in FIG. 6H. By the method indicated by these processes, one wiring laminated body can be formed. By such a method, the first insulating layer 6 is formed between layers of the first wiring layer 2 and an upper portion thereof. Therefore, the first insulating layer 6 and the third insulating layer 9 are formed of the same material.

A process for forming the resistance change region 5 will be further described. By treating the multilayer graphene (first wiring layer 2) into which an interlayer substance has been inserted with an atmosphere containing an oxidizing gas, a nitriding gas, or an oxidizing gas and a nitriding gas, the resistance change region 5 can be formed. As the oxidizing gas, a gas having an oxidizing effect such as an oxygen gas, an ozone gas, an oxygen plasma gas, or a dinitrogen monoxide plasma gas is preferably used. As the nitriding gas, a gas having a nitriding effect such as ammonia, ammonia plasma, or nitrogen plasma is preferably used. In the treatment in the atmosphere containing an oxidizing gas and a nitriding gas, the multilayer graphene may be treated with an atmosphere containing an oxidizing gas and a nitriding gas, the multilayer graphene may be treated with an atmosphere containing an oxidizing gas and then further with an atmosphere containing a nitriding gas, or the multilayer graphene may be treated with an atmosphere containing a nitriding gas and then further with an atmosphere containing an oxidizing gas.

When a metal chloride is used for an interlayer substance, the metal chloride reacts with an oxygen atom or a nitrogen atom in an atmosphere containing an oxidizing gas, a nitriding gas, or an oxidizing gas and a nitriding gas, and a part of the interlayer substance becomes an oxide, a nitride, or an oxynitride. When a metal chloride is used for an interlayer substance, by treating the multilayer graphene with an atmosphere containing a metal or a metal chloride and an oxidizing gas or a nitriding gas, a part of the interlayer substance or a metal contained in the treatment atmosphere reacts with the oxidizing gas or the nitriding gas to generate an oxide, a nitride, or an oxynitride.

When a metal chloride is not used for an interlayer substance, by treating the multilayer graphene with an atmosphere containing a metal or a metal chloride and an oxidizing gas or a nitriding gas, a metal contained in the treatment atmosphere reacts with the oxidizing gas or the nitriding gas to generate an oxide, a nitride, or an oxynitride. By performing these treatments, an oxidizing gas or a nitriding gas as a reactive gas enters the multilayer graphene (first wiring layer 2) from a defect or a grain boundary thereof to react. Formation of the resistance change region 5 is preferable from a viewpoint of preventing leakage of the interlayer substance.

### Second Embodiment

A second embodiment relates to a nonvolatile storage device using a graphene conductor. The second embodiment is a modified example of the nonvolatile storage device of the first embodiment. The nonvolatile storage device of the second embodiment is different from the nonvolatile storage device of the first embodiment in that the nonvolatile storage device of the second embodiment includes a resistance change region in each of a first wiring layer 2 and a second wiring layer 3.

FIG. 7 illustrates a schematic cross sectional view of a nonvolatile storage device 101 of the second embodiment. The nonvolatile storage device 101 in FIG. 7 includes a substrate 1, the first wiring layer 2 extending in a first direction, the second wiring layer 3 extending in a second direction intersecting with the first direction, a conductive layer 4 at an intersection of the first wiring layer 2 and the second wiring layer 3, a resistance change region 5 including at least one of an oxide, a nitride, and an oxynitride in the first wiring layer 2, a first insulating layer 6 sandwiching the conductive layer 4, and a second insulating layer 7 sandwiching the second wiring layer 3. The resistance change region 5 exists in a region including a surface of the first wiring layer 2. The first wiring layer 2 is connected to the conductive layer 4 through the resistance change region 5. A third insulating layer 9 not illustrated in FIG. 1 is illustrated in the nonvolatile storage device 101, and sandwiches the first wiring layer 2. The first wiring layer 2 and the second wiring layer 3 are connected to a control unit 8.

In the nonvolatile storage device 101 of the second embodiment, by disposing the resistance change region 5 in each of the first wiring layer 2 and the second wiring layer 3, a density of a memory element can be increased. A method for manufacturing the nonvolatile storage device of the second embodiment may be obtained by forming the resistance change region 5 not only in the first wiring layer 2 but also in the second wiring layer 3 by partially changing the manufacturing method in the first embodiment.

### Third Embodiment

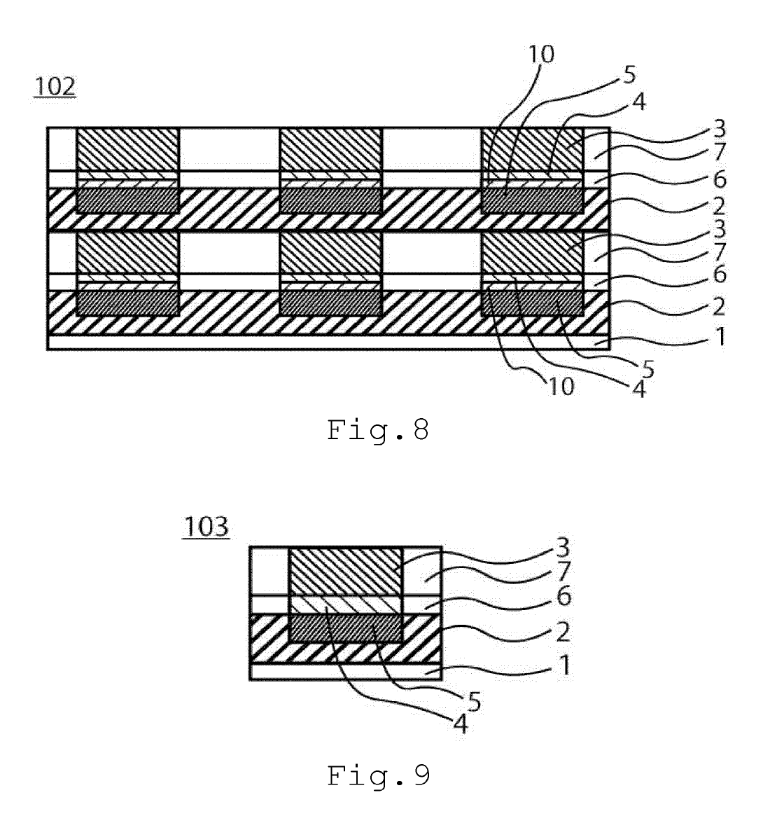

A third embodiment relates to a nonvolatile storage device 102 using a graphene conductor. FIG. 8 illustrates a schematic cross sectional view of the nonvolatile storage device of the third embodiment. The third embodiment is a modified example of the nonvolatile storage device of the first embodiment. The nonvolatile storage device of the third embodiment is different from the nonvolatile storage device of the first embodiment in that the nonvolatile storage device of the third embodiment further includes a buffer layer 10 in a conductive layer 4. A resistance change region 5 exists in an interface between the buffer layer 10 in the conductive layer 4 and the first wiring layer 2.

For example, when the conductive layer 4 cannot be formed directly on the resistance change region 5, the buffer layer 10 is introduced as a base layer of the conductive layer 4. The buffer layer 10 is preferably thin to such a degree that conductivity between the conductive layer 4 and the first wiring layer 2 is not inhibited. Therefore, the thickness of the buffer layer 10 is preferably 10 nm or less, and more preferably 3 nm or less. For example, the buffer layer 10 is introduced as a tunnel barrier for enhancing a rectification function between the conductive layer 4 and the first wiring layer 2. Also in this case, the thickness of the buffer layer 10 is preferably 10 nm or less, and more preferably 3 nm or less.

### Fourth Embodiment

A fourth embodiment relates to a semiconductor element (switch) using a graphene conductor. The semiconductor element acting as the switch of the embodiment will be described using the schematic cross sectional view of a semiconductor element 103 in FIG. 9. The switch illustrated in the schematic cross sectional view of FIG. 9 includes a substrate 1, a first wiring layer 2 extending in a first direction, a second wiring layer 3 extending in a second direction intersecting with the first direction, a conductive layer 4 at an intersection of the first wiring layer 2 and the second wiring layer 3, a resistance change region 5 including at least one of an oxide, a nitride, and an oxynitride in the first wiring layer 2, a first insulating layer 6 sandwiching the conductive layer 4, and a second insulating layer 7 sandwiching the second wiring layer 3. The resistance change region 5 exists in a region including a surface of the first wiring layer 2. The first wiring layer 2 is connected to the conductive layer 4 through the resistance change region 5. The switch 103 of the fourth embodiment is common to the nonvolatile storage device of any one of the first to third embodiments except for particularly described points thereof. Points of the switch 103 of the fourth embodiment common to the nonvolatile storage device will not be described.

The resistance change region 5 of the switch 103 can change a resistance property by an applied voltage or a current similarly to the resistance change region of the nonvolatile storage device. Time when the resistance change region 5 has a high resistance or is insulated can be off of the switch. Time when the resistance change region 5 has a low resistance can be on of the switch. The first wiring layer 2 and the second wiring layer 3 are each connected to an element in a circuit such as another semiconductor element (not illustrated). The switch 103 has a rectification property as described in another embodiment, and therefore can act as a switch capable of limiting a current direction.

### Fifth Embodiment

A fifth embodiment relates to a semiconductor element (diode) using a graphene conductor. The semiconductor element acting as the diode of the embodiment will be described using the schematic cross sectional view of a semiconductor element 103 in FIG. 9. The diode 103 of the fifth embodiment is common to the nonvolatile storage device of any one of the first to third embodiments except for particularly described points thereof. Points of the diode 103 of the fifth embodiment common to the nonvolatile storage device will not be described. In the diode 103 of the embodiment, a first wiring layer 2 as a semiconductor, a resistance change region 5, and a conductive layer 4 are bonded sequentially. This structure is an M (metal)-I (insulating film)-S (semiconductor) structure, and therefore has a rectification property as a diode.

### Sixth Embodiment

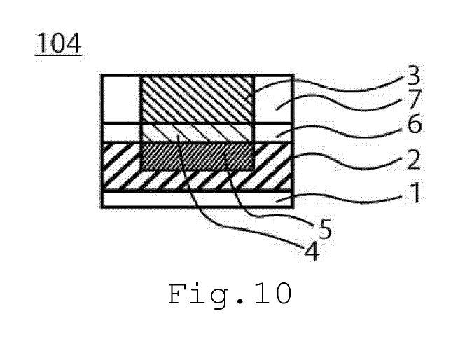

A sixth embodiment relates to a capacitor using a graphene conductor. The capacitor of the embodiment will be described using the schematic cross sectional view of a capacitor 104 in FIG. 10. The capacitor 104 of the sixth embodiment is common to the nonvolatile storage device of any one of the first to third embodiments except for particularly described points thereof. Points of the capacitor 104 of the sixth embodiment common to the nonvolatile storage device will not be described.

A first wiring layer 2 is a semiconductor but has conductivity of both types due to an interlayer substance. Therefore, the capacitor 104 acts as a capacitor by holding an insulating resistance change region 5 with a conductive layer 4 and the first wiring layer 2. The capacitor 104 can change characteristics thereof by changing a resistance property of the resistance change region 5.

Here, some elements are expressed only by element symbols thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile storage device comprising:
a first wiring layer extending in a first direction;
a second wiring layer extending in a second direction intersecting with the first direction;
a conductive layer between the first wiring layer and the second wiring layer at an intersection of the first wiring layer and the second wiring layer; and
a resistance change region including at least one of an oxide, a nitride, and an oxynitride in the first wiring layer, wherein
the resistance change region exists in the first wiring layer including an interface between the first wiring layer and the conductive layer.

2. The device according to claim 1, wherein each of the first wiring layer and the second wiring layer includes a multilayer graphene and an interlayer substance between layers of the multilayer graphene.

3. The device according to claim 2, wherein
the interlayer substance contains at least one of a metal chloride, a metal fluoride, a metal bromide, and a metal oxide, and
each of the metal chloride, the metal fluoride, the metal bromide, and the metal oxide contains at least one element selected from the group consisting of; Ta, Ti, Ni, Fe, Mo, Hf, Co, Cu, Ag, Zn, W, Al, Zr, Cr, V, Bi, and Mn.

4. The device according to claim 1, wherein the conductive layer contains at least one element selected from the group consisting of; Cu, Ag, Ti, Pt, Ta, W, Ni, Co, Al, Mo, Ir, Au, and Ru.

5. The device according to claim 1, wherein a resistance in the resistance change region is changed by a voltage applied to the resistance change region or a current flowing in the resistance change region.

6. A semiconductor element comprising:
a first wiring layer extending in a first direction;
a second wiring layer extending in a second direction intersecting with the first direction;
a conductive layer between the first wiring layer and the second wiring layer at an intersection of the first wiring layer and the second wiring layer; and
a resistance change region including at least one of an oxide, a nitride, and an oxynitride in the first wiring layer, wherein
the resistance change region exists in an interface between the first wiring layer and the conductive layer.

7. The element according to claim 6, wherein each of the first wiring layer and the second wiring layer includes a multilayer graphene and an interlayer substance between layers of the multilayer graphene.

8. The element according to claim 7, wherein
the interlayer substance contains at least one of a metal chloride, a metal fluoride, a metal bromide, and a metal oxide, and
each of the metal chloride, the metal fluoride, the metal bromide, and the metal oxide contains at least one element selected from the group consisting of; Ta, Ti, Ni, Fe, Mo, Hf, Co, Cu, Ag, Zn, W, Al, Zr, Cr, V, Bi, and Mn.

9. The element according to claim 6, wherein the conductive layer contains at least one element selected from the group consisting of; Cu, Ag, Ti, Pt, Ta, W, Ni, Co, Al, Mo, Ir, Au, and Ru.

10. The element according to claim 6, wherein a resistance in the resistance change region is changed by a voltage applied to the resistance change region or a current flowing in the resistance change region.

11. A capacitor comprising:
a first wiring layer extending in a first direction;
a second wiring layer extending in a second direction intersecting with the first direction;
a conductive layer between the first wiring layer and the second wiring layer at an intersection of the first wiring layer and the second wiring layer; and
a resistance change region including at least one of an oxide, a nitride, and an oxynitride in the first wiring layer, wherein
the resistance change region exists in an interface between the first wiring layer and the conductive layer.

12. The capacitor according to claim 11, wherein each of the first wiring layer and the second wiring layer includes a multilayer graphene and an interlayer substance between layers of the multilayer graphene.

13. The capacitor according to claim 12, wherein
the interlayer substance contains at least one of a metal chloride, a metal fluoride, a metal bromide, and a metal oxide, and
each of the metal chloride, the metal fluoride, the metal bromide, and the metal oxide contains at least one element selected from the group consisting of; Ta, Ti, Ni, Fe, Mo, Hf, Co, Cu, Ag, Zn, W, Al, Zr, Cr, V, Bi, and Mn.

14. The capacitor according to claim 11, wherein the conductive layer contains at least one element selected from the group consisting of; Cu, Ag, Ti, Pt, Ta, W, Ni, Co, Al, Mo, Ir, Au, and Ru.

15. The capacitor according to claim 11, wherein a resistance in the resistance change region is changed by a voltage applied to the resistance change region or a current flowing in the resistance change region.
